(19) United States
(12) Patent Application Publication
(10) Pub. No.: US 2026/0112423 A1
(43) Pub. Date: Apr. 23, 2026

(54) NONVOLATILE MEMORY WITH VOLTAGE OVERSHOOT MITIGATION

(71) Applicant: Sandisk Technologies, Inc., Milpitas, CA (US)

(72) Inventors: Shivasubramaniyarajan VM, Bengaluru (IN); Ayan Saikia, Bengaluru (IN); Madhu Preetha B R, Bengaluru (IN); V.S.N.K. Chaitanya G, Bengaluru (IN); Indra Kumar K V, Bengaluru (IN)

(73) Assignee: Sandisk Technologies, Inc., Milpitas, CA (US)

(21) Appl. No.: 18/919,469

(22) Filed: Oct. 18, 2024

(51) Int. Cl. G11C 16/30; G11C 16/08; G11C 16/28

(52) U.S. Cl. CPC G11C 16/30; G11C 16/08; G11C 16/28

(57) ABSTRACT

An apparatus includes control circuits configured to connect to a plurality of nonvolatile memory cells. The one or more control circuits are configured to apply a predetermined voltage on one or more word lines connected to the nonvolatile memory cells in a memory access operation and limit overshoot of the predetermined voltage by controlling a discharge pathway at an output terminal according to an analog control signal. The analog control signal is proportional to voltage overshoot of the predetermined voltage.

### BACKGROUND

The present technology relates to non-volatile memory and circuits and methods for accessing non-volatile memory.

Semiconductor memory is widely used in various electronic devices such as cellular telephones, digital cameras, personal digital assistants, medical electronics, mobile computing devices, servers, solid state drives, non-mobile computing devices and other devices. Semiconductor memory may comprise non-volatile memory or volatile memory. Non-volatile memory allows information to be stored and retained even when the non-volatile memory is not connected to a source of power (e.g., a battery).

A memory structure in the memory system typically contains many memory cells and various control lines. The memory structure may be three-dimensional. One type of three-dimensional structure has non-volatile memory cells arranged as vertical NAND strings. The memory structure may be arranged into units that are commonly referred to as blocks. For example, a block in a NAND memory system contains many NAND strings. Each NAND string is associated with a bit line. The block typically has many word lines that provide voltages to the control gates of the memory cell transistors. In some architectures, each word line connects to the control gate of one memory cell on each respective NAND string in the block.

Non-volatile memory cells may be programmed to store data. Memory cells may be programmed to a number of data states. Some memory cells may be programmed to a data state by storing charge in the memory cell in a program or write operation. Data states of memory cells may be obtained in a read operation. Memory cells may be erased in an erase operation. Memory access operations such as read, write and erase operations may involve applying appropriate memory access voltages on components of a memory structure including word lines. Providing appropriate memory access voltages may be challenging (e.g., voltage may overshoot and/or may take significant time to stabilize). Design of control circuits to provide appropriate memory access voltages may be challenging.

### BRIEF DESCRIPTION OF THE DRAWINGS

Like-numbered elements refer to common components in the different figures.

FIG. 1 is a block diagram depicting one embodiment of a storage system.

FIG. 2A is a block diagram of one embodiment of a memory die.

FIG. 2B is a block diagram of one embodiment of an integrated memory assembly.

FIG. 3 shows an example of a portion of a memory structure.

FIGS. 4A-G illustrate an example of a memory structure.

FIGS. 5A and 5B depict threshold voltage distributions.

FIG. 6 shows an example of applying read voltages to read memory cells.

FIG. 7 shows an example of control circuits to provide a memory access voltage.

FIG. 8 shows an example of control circuits to provide a memory access voltage, including a voltage discharge pathway.

FIG. 9 shows examples of recovery time in memory access voltages.

FIGS. 10A-B show examples of droop in memory access voltages.

FIG. 11 shows an example of a method that includes discharging an output terminal through a discharge pathway controlled by an analog control signal.

### DETAILED DESCRIPTION

Technology is disclosed herein for providing voltages that may be used to access memory cells in a memory structure (e.g., during memory access operations such as read, write and erase operations), for example, providing a voltage on a component of a memory structure (e.g., word line) during a memory access operation (e.g., read). Memory operation may be improved by providing a clean voltage (e.g., a voltage that remains at or close to a desired voltage and stabilizes rapidly when deviation from the desired voltage occurs). Deviations from a desired voltage may occur due to voltage overshoot, undershoot, droop and/or other reasons. Aspects of the present technology may limit or eliminate deviations due to one or more such reasons.

In an example, control circuits provide a voltage output at an output node that may be connected to a memory structure component (e.g., word line, bit line, select line). The output node may be connected to a push-pull output stage that includes a discharge pathway to discharge current from the output node. Such a discharge pathway may allow a discharge current to flow from the output node and thereby reduce voltage at the output node (e.g., when a voltage overshoot occurs). A discharge pathway may be provided by a PMOS device that is controlled by an analog signal so that the magnitude of the discharge current may be controlled appropriately (e.g., according to the degree of voltage overshoot). Controlling the discharge pathway using a Push-Pull architecture with NMOS Current source at the top and PMOS Current sink at the bottom may provide various advantages.

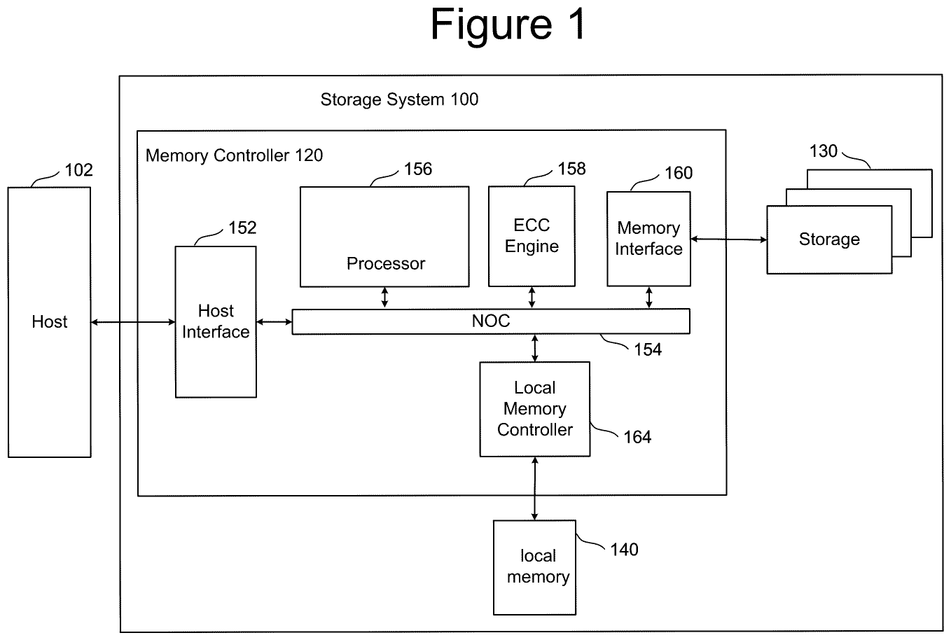

FIG. 1 is a block diagram of one embodiment of a storage system 100 that implements the technology described herein. In one embodiment, storage system 100 is a solid state drive (“SSD”). Storage system 100 can also be a memory card, USB drive or other type of storage system. The proposed technology is not limited to any one type of storage system. Storage system 100 is connected to host 102, which can be a computer, server, electronic device (e.g., smart phone, tablet or other mobile device), appliance, or another apparatus that uses memory and has data processing capabilities. In some embodiments, host 102 is separate from, but connected to, storage system 100. In other embodiments, storage system 100 is embedded within host 102.

The components of storage system 100 depicted in FIG. 1 are electrical circuits. Storage system 100 includes a memory controller 120 (or storage controller) connected to non-volatile storage 130 and local high speed memory 140 (e.g., DRAM, SRAM, MRAM). Local memory 140 is non-transitory memory, which may include volatile memory or non-volatile memory. Local high speed memory 140 is used by memory controller 120 to perform certain operations. For example, local high speed memory 140 may store logical to physical address translation tables (“L2P tables”).

Memory controller 120 comprises a host interface 152 that is connected to and in communication with host 102. In one embodiment, host interface 152 implements an NVM Express (NVMe) over PCI Express (PCIe). Other interfaces can also be used, such as SCSI, SATA, etc. Host interface 152 is also connected to a network-on-chip (NOC) 154. A NOC is a communication subsystem on an integrated circuit. NOC's can span synchronous and asynchronous clock domains or use unclocked asynchronous logic. NOC technology applies networking theory and methods to on-chip communications and brings notable improvements over conventional bus and crossbar interconnections. NOC improves the scalability of systems on a chip (SoC) and the power efficiency of complex SoCs compared to other designs. The wires and the links of the NOC are shared by many signals. A high level of parallelism is achieved because all links in the NOC can operate simultaneously on different data packets. Therefore, as the complexity of integrated subsystems keep growing, a NOC provides enhanced performance (such as throughput) and scalability in comparison with previous communication architectures (e.g., dedicated point-to-point signal wires, shared buses, or segmented buses with bridges). In other embodiments, NOC 154 can be replaced by a bus.

Connected to and in communication with NOC 154 is processor 156, ECC engine 158, memory interface 160, and local memory controller 164. Local memory controller 164 is used to operate and communicate with local high speed memory 140 (e.g., DRAM, SRAM, MRAM).

ECC engine 158 performs error correction services. For example, ECC engine 158 performs data encoding and decoding. In one embodiment, ECC engine 158 is an electrical circuit programmed by software. For example, ECC engine 158 can be a processor that can be programmed. In other embodiments, ECC engine 158 is a custom and dedicated hardware circuit without any software. In another embodiment, the function of ECC engine 158 is implemented by processor 156.

Processor 156 performs the various controller memory operations, such as programming, erasing, reading, and memory management processes. In one embodiment, processor 156 is programmed by firmware. In other embodiments, processor 156 is a custom and dedicated hardware circuit without any software. Processor 156 also implements a translation module, as a software/firmware process or as a dedicated hardware circuit. In many systems, the non-volatile memory is addressed internally to the storage system using physical addresses associated with the one or more memory die. However, the host system will use logical addresses to address the various memory locations. This enables the host to assign data to consecutive logical addresses, while the storage system is free to store the data as it wishes among the locations of the one or more memory die. To implement this system, memory controller 120 (e.g., the translation module) performs address translation between the logical addresses used by the host and the physical addresses used by the memory die. One example implementation is to maintain tables (i.e. the L2P tables mentioned above) that identify the current translation between logical addresses and physical addresses. An entry in the L2P table may include an identification of a logical address and corresponding physical address. Although logical address to physical address tables (or L2P tables) include the word “tables” they need not literally be tables. Rather, the logical address to physical address tables (or L2P tables) can be any type of data structure. In some examples, the memory space of a storage system is so large that the local memory 140 cannot hold all of the L2P tables. In such a case, the entire set of L2P tables are stored in a storage 130 and a subset of the L2P tables are cached (L2P cache) in the local high speed memory 140.

Memory interface 160 communicates with non-volatile storage 130. In one embodiment, memory interface 160 provides a Toggle Mode interface. Other interfaces can also be used. In some example implementations, memory interface 160 (or another portion of memory controller 120) implements a scheduler and buffer for transmitting data to and receiving data from one or more memory die.

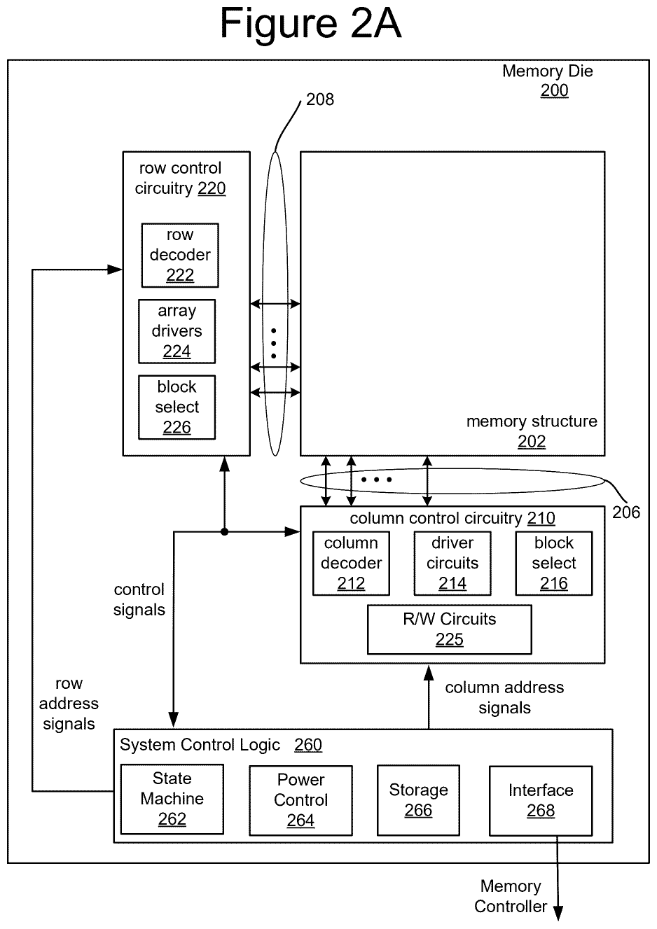

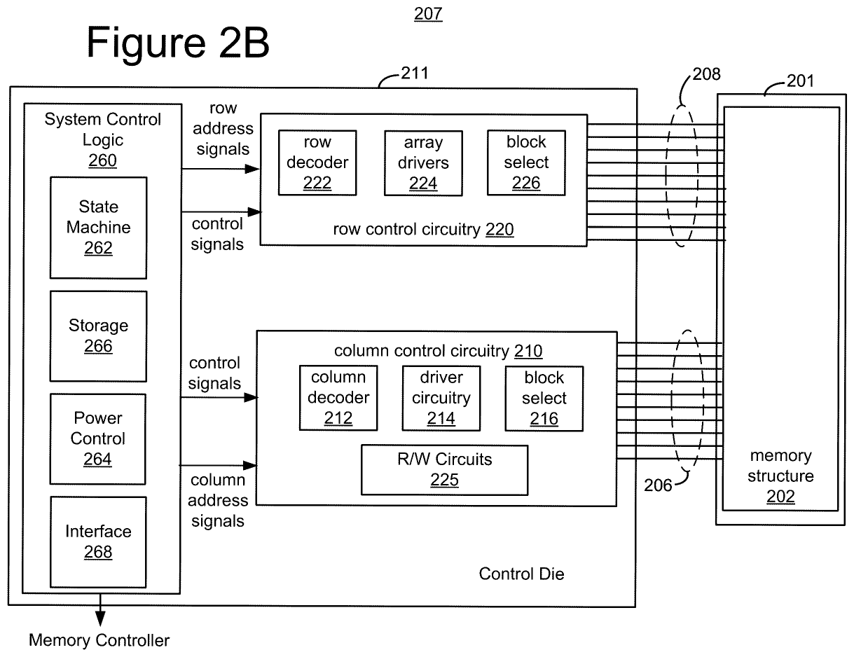

In one embodiment, non-volatile storage 130 comprises one or more memory dies. FIG. 2A is a functional block diagram of one embodiment of a memory die 200 that comprises non-volatile storage 130. Each of the one or more memory dies of non-volatile storage 130 can be implemented as memory die 200 of FIG. 2A. The components depicted in FIG. 2A are electrical circuits. Memory die 200 includes a memory structure 202 (e.g., memory array) that can comprise non-volatile memory cells (also referred to as non-volatile storage cells), as described in more detail below. The array terminal lines of memory structure 202 include the various layer(s) of word lines organized as rows, and the various layer(s) of bit lines organized as columns. However, other orientations can also be implemented. Memory die 200 includes row control circuitry 220, whose outputs are connected to respective word lines of the memory structure 202. Row control circuitry 220 receives a group of M row address signals and one or more various control signals from System Control Logic 260, and typically may include such circuits as row decoders 222, array drivers 224, and block select circuit 226 for both reading and writing (programming) operations. Row control circuitry 220 may also include read/write circuitry. Memory die 200 also includes column control circuitry 210 including read/write circuits 225. The read/write circuits 225 may contain sense amplifiers and data latches. The sense amplifier(s) input/outputs are connected to respective bit lines of the memory structure 202. Although only a single block is shown for memory structure 202, a memory die can include multiple arrays that can be individually accessed. Column control circuitry 210 receives a group of N column address signals and one or more various control signals from System Control Logic 260, and typically may include such circuits as column decoders 212, array terminal receivers or driver circuits 214, block select circuit 216, as well as read/write circuitry, and I/O multiplexers.

System control logic 260 receives data and commands from memory controller 120 and provides output data and status to the host. In some embodiments, the system control logic 260 (which comprises one or more electrical circuits) includes state machine 262 that provides die-level control of memory operations. In one embodiment, the state machine 262 is programmable by software. In other embodiments, the state machine 262 does not use software and is completely implemented in hardware (e.g., electrical circuits). In another embodiment, the state machine 262 is replaced by a micro-controller or microprocessor, either on or off the memory chip. System control logic 260 can also include a power control module 264 that controls the power and voltages supplied to the rows and columns of the memory structure 202 during memory operations. System control logic 260 includes storage 266 (e.g., RAM, registers, latches, etc.), which may be used to store parameters for operating the memory structure 202.

Commands and data are transferred between memory controller 120 and memory die 200 via memory controller interface 268 (also referred to as a “communication interface”). Memory controller interface 268 is an electrical interface for communicating with memory controller 120. Examples of memory controller interface 268 include a Toggle Mode Interface and an Open NAND Flash Interface (ONFI). Other I/O interfaces can also be used.

In some embodiments, all the elements of memory die 200, including the system control logic 260, can be formed as part of a single die. In other embodiments, some or all of the system control logic 260 can be formed on a different die than the die that contains the memory structure 202.

In one embodiment, memory structure 202 comprises a three-dimensional memory array of non-volatile memory cells in which multiple memory levels are formed above a single substrate, such as a wafer. The memory structure may comprise any type of non-volatile memory that are monolithically formed in one or more physical levels of memory cells having an active area disposed above a silicon (or other type of) substrate. In one example, the non-volatile memory cells comprise vertical NAND strings with charge-trapping layers.

In another embodiment, memory structure 202 comprises a two-dimensional memory array of non-volatile memory cells. In one example, the non-volatile memory cells are NAND flash memory cells utilizing floating gates. Other types of memory cells (e.g., NOR-type flash memory) can also be used.

The exact type of memory array architecture or memory cell included in memory structure 202 is not limited to the examples above. Many different types of memory array architectures or memory technologies can be used to form memory structure 202. No particular non-volatile memory technology is required for purposes of the new claimed embodiments proposed herein. Other examples of suitable technologies for memory cells of the memory structure 202 include ReRAM memories (resistive random access memories), magnetoresistive memory (e.g., MRAM, Spin Transfer Torque MRAM, Spin Orbit Torque MRAM), FeRAM, phase change memory (e.g., PCM), and the like. Examples of suitable technologies for memory cell architectures of the memory structure 202 include two dimensional arrays, three dimensional arrays, cross-point arrays, stacked two dimensional arrays, vertical bit line arrays, and the like.

One example of a ReRAM cross-point memory includes reversible resistance-switching elements arranged in cross-point arrays accessed by X lines and Y lines (e.g., word lines and bit lines). In another embodiment, the memory cells may include conductive bridge memory elements. A conductive bridge memory element may also be referred to as a programmable metallization cell. A conductive bridge memory element may be used as a state change element based on the physical relocation of ions within a solid electrolyte. In some cases, a conductive bridge memory element may include two solid metal electrodes, one relatively inert (e.g., tungsten) and the other electrochemically active (e.g., silver or copper), with a thin film of the solid electrolyte between the two electrodes. As temperature increases, the mobility of the ions also increases causing the programming threshold for the conductive bridge memory cell to decrease. Thus, the conductive bridge memory element may have a wide range of programming thresholds over temperature.

Another example is magnetoresistive random access memory (MRAM) that stores data by magnetic storage elements. The elements are formed from two ferromagnetic layers, each of which can hold a magnetization, separated by a thin insulating layer. One of the two layers is a permanent magnet set to a particular polarity; the other layer's magnetization can be changed to match that of an external field to store memory. A memory device is built from a grid of such memory cells. In one embodiment for programming, each memory cell lies between a pair of write lines arranged at right angles to each other, parallel to the cell, one above and one below the cell. When current is passed through them, an induced magnetic field is created. MRAM based memory embodiments will be discussed in more detail below.

Phase change memory (PCM) exploits the unique behavior of chalcogenide glass. One embodiment uses a GeTe—Sb2Te3 super lattice to achieve non-thermal phase changes by simply changing the co-ordination state of the Germanium atoms with a laser pulse (or light pulse from another source). Therefore, the doses of programming are laser pulses. The memory cells can be inhibited by blocking the memory cells from receiving the light. In other PCM embodiments, the memory cells are programmed by current pulses. Note that the use of “pulse” in this document does not require a square pulse but includes a (continuous or non-continuous) vibration or burst of sound, current, voltage light, or other wave. These memory elements within the individual selectable memory cells, or bits, may include a further series element that is a selector, such as an ovonic threshold switch or metal insulator substrate.

A person of ordinary skill in the art will recognize that the technology described herein is not limited to a single specific memory structure, memory construction or material composition, but covers many relevant memory structures within the spirit and scope of the technology as described herein and as understood by one of ordinary skill in the art.

The elements of FIG. 2A can be grouped into two parts: (1) memory structure 202 and (2) peripheral circuitry, which includes all of the other components depicted in FIG. 2A. An important characteristic of a memory circuit is its capacity, which can be increased by increasing the area of the memory die of storage system 100 that is given over to the memory structure 202; however, this reduces the area of the memory die available for the peripheral circuitry. This can place quite severe restrictions on these elements of the peripheral circuitry. For example, the need to fit sense amplifier circuits within the available area can be a significant restriction on sense amplifier design architectures. With respect to the system control logic 260, reduced availability of area can limit the available functionalities that can be implemented on-chip. Consequently, a basic trade-off in the design of a memory die for the storage system 100 is the amount of area to devote to the memory structure 202 and the amount of area to devote to the peripheral circuitry.

Another area in which the memory structure 202 and the peripheral circuitry are often at odds is in the processing involved in forming these regions, since these regions often involve differing processing technologies and the trade-off in having differing technologies on a single die. For example, when the memory structure 202 is NAND flash, this is an NMOS structure, while the peripheral circuitry is often CMOS based. For example, elements such sense amplifier circuits, charge pumps, logic elements in a state machine, and other peripheral circuitry in system control logic 260 often employ PMOS devices. Processing operations for manufacturing a CMOS die will differ in many aspects from the processing operations optimized for an NMOS flash NAND memory or other memory cell technologies. Three-dimensional NAND structures in particular may benefit from specialized processing operations.

To improve upon these limitations, embodiments described below can separate the elements of FIG. 2A onto separately formed dies that are then bonded together. More specifically, the memory structure 202 can be formed on one die (referred to as the memory die) and some or all of the peripheral circuitry elements, including one or more control circuits, can be formed on a separate die (referred to as the control die). For example, a memory die can be formed of just the memory elements, such as the array of memory cells of flash NAND memory, MRAM memory, PCM memory, ReRAM memory, or other memory type. Some or all of the peripheral circuitry, even including elements such as decoders and sense amplifiers, can then be moved on to a separate control die. This allows each of the memory die to be optimized individually according to its technology. For example, a NAND memory die can be optimized for an NMOS based memory array structure, without worrying about the CMOS elements that have now been moved onto a control die that can be optimized for CMOS processing. This allows more space for the peripheral elements, which can now incorporate additional capabilities that could not be readily incorporated were they restricted to the margins of the same die holding the memory cell array. The two die can then be bonded together in a bonded multi-die memory circuit, with the array on the one die connected to the periphery elements on the other die. Although the following will focus on a bonded memory circuit of one memory die and one control die, other embodiments can use more die, such as two memory die and one control die, for example.

FIG. 2B shows an alternative arrangement to that of FIG. 2A which may be implemented using wafer-to-wafer bonding to provide a bonded die pair. FIG. 2B depicts a functional block diagram of one embodiment of an integrated memory assembly 207. One or more integrated memory assemblies 207 may be used to implement the non-volatile storage 130 of storage system 100. The integrated memory assembly 207 includes two types of semiconductor dies (or more succinctly, “die”). Memory structure die 201 includes memory structure 202. Memory structure 202 includes non-volatile memory cells. Control die 211 includes control circuitry 260, 210, and 220 (as described above). In some embodiments, control die 211 is configured to connect to the memory structure 202 in the memory structure die 201. In some embodiments, the memory structure die 201 and the control die 211 are bonded together.

FIG. 2B shows an example of the peripheral circuitry, including control circuits, formed in a peripheral circuit or control die 211 coupled to memory structure 202 formed in memory structure die 201. Common components are labelled similarly to FIG. 2A. System control logic 260, row control circuitry 220, and column control circuitry 210 are located in control die 211. In some embodiments, all or a portion of the column control circuitry 210 and all or a portion of the row control circuitry 220 are located on the memory structure die 201. In some embodiments, some of the circuitry in the system control logic 260 is located on the on the memory structure die 201.

System control logic 260, row control circuitry 220, and column control circuitry 210 may be formed by a common process (e.g., CMOS process), so that adding elements and functionalities, such as ECC, more typically found on a memory controller 120 may require few or no additional process steps (i.e., the same process steps used to fabricate memory controller 120 may also be used to fabricate system control logic 260, row control circuitry 220, and column control circuitry 210). Thus, while moving such circuits from a die such as memory structure die 201 may reduce the number of steps needed to fabricate such a die, adding such circuits to a die such as control die 211 may not require many additional process steps. The control die 211 could also be referred to as a CMOS die, due to the use of CMOS technology to implement some or all of control circuitry 260, 210, 220.

FIG. 2B shows column control circuitry 210 including read/write circuits 225 on the control die 211 coupled to memory structure 202 on the memory structure die 201 through electrical paths 206. For example, electrical paths 206 may provide electrical connection between column decoder 212, driver circuits 214, and block select circuit 216 and bit lines of memory structure 202. Electrical paths may extend from column control circuitry 210 in control die 211 through pads on control die 211 that are bonded to corresponding pads of the memory structure die 201, which are connected to bit lines of memory structure 202. Each bit line of memory structure 202 may have a corresponding electrical path in electrical paths 206, including a pair of bond pads, which connects to column control circuitry 210. Similarly, row control circuitry 220, including row decoder 222, array drivers 224, and block select circuit 226 are coupled to memory structure 202 through electrical paths 208. Each of electrical path 208 may correspond to a word line, dummy word line, or select gate line. Additional electrical paths may also be provided between control die 211 and memory structure die 201.

For purposes of this document, the phrases “a control circuit” or “one or more control circuits” can include any one of or any combination of memory controller 120, state machine 262, power control module 264, all or a portion of system control logic 260, all or a portion of row control circuitry 220, all or a portion of column control circuitry 210, read/write circuits 225, sense amps, a microcontroller, a microprocessor, and/or other similar functioned circuits. A control circuit can include hardware only or a combination of hardware and software (including firmware). For example, a controller programmed by firmware to perform the functions described herein is one example of a control circuit. A control circuit can include a processor, FPGA, ASIC, integrated circuit, or other type of circuit.

For purposes of this document, the term “apparatus” can include, but is not limited to, one or more of, storage system 100, memory controller 120, storage 130, memory die 200, integrated memory assembly 207, and/or control die 211.

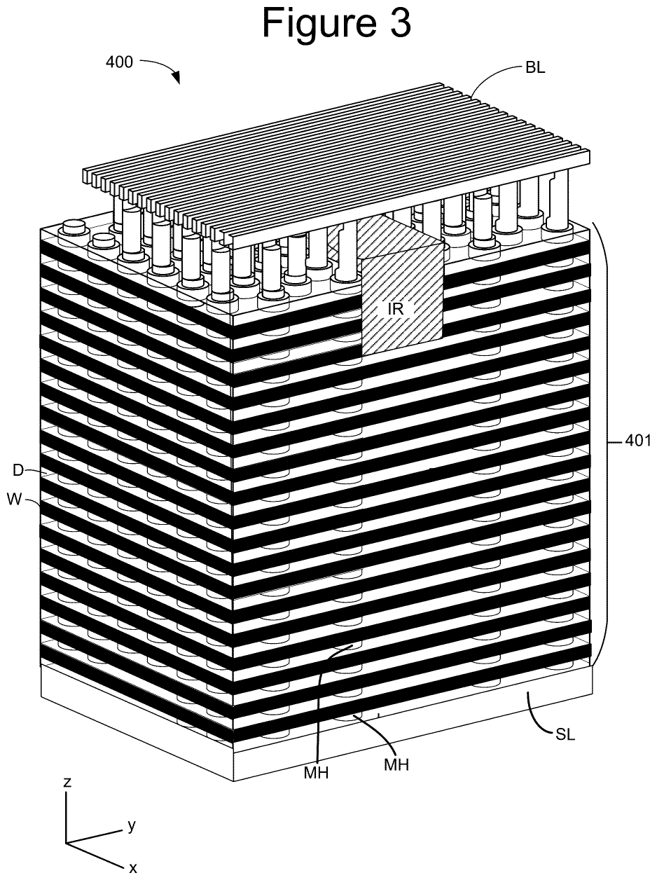

FIG. 3 is a perspective view of a portion of one example embodiment of a monolithic three dimensional memory array/structure that can comprise memory structure 202, which includes a plurality non-volatile memory cells arranged as vertical NAND strings. For example, FIG. 3 shows a portion 400 of one block of memory. The structure depicted includes a set of bit lines BL positioned above a stack 401 of alternating dielectric layers and conductive layers. For example purposes, one of the dielectric layers is marked as D and one of the conductive layers (also called word line layers) is marked as W. The number of alternating dielectric layers and conductive layers can vary based on specific implementation requirements. In one embodiment the alternating dielectric layers and conductive layers are divided into four (or a different number of) regions (e.g., sub-blocks) by isolation regions IR. FIG. 3 shows one isolation region IR separating two sub-blocks. Below the alternating dielectric layers and word line layers is a source line layer SL. Memory holes are formed in the stack of alternating dielectric layers and conductive layers. For example, one of the memory holes is marked as MH. Note that in FIG. 3, the dielectric layers are depicted as see-through so that the reader can see the memory holes positioned in the stack of alternating dielectric layers and conductive layers. In one embodiment, NAND strings are formed by filling the memory hole with materials including a charge-trapping material to create a vertical column of memory cells. Each memory cell can store one or more bits of data. More details of the three dimensional monolithic memory array that comprises memory structure 202 is provided below.

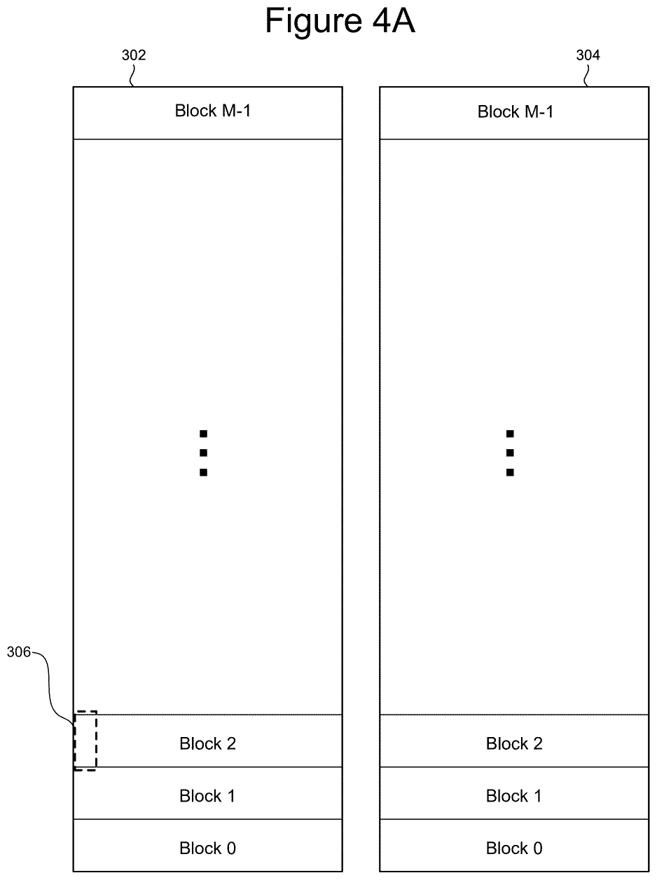

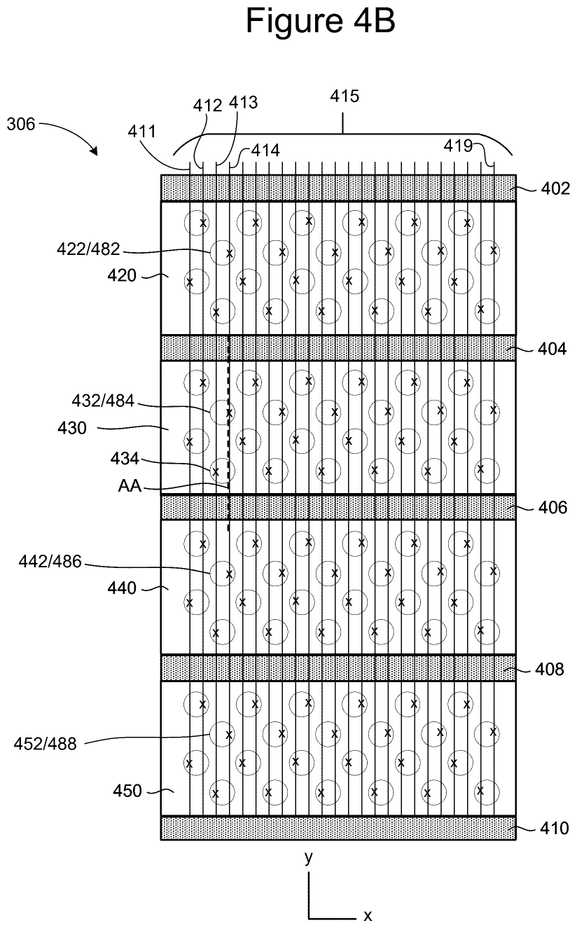

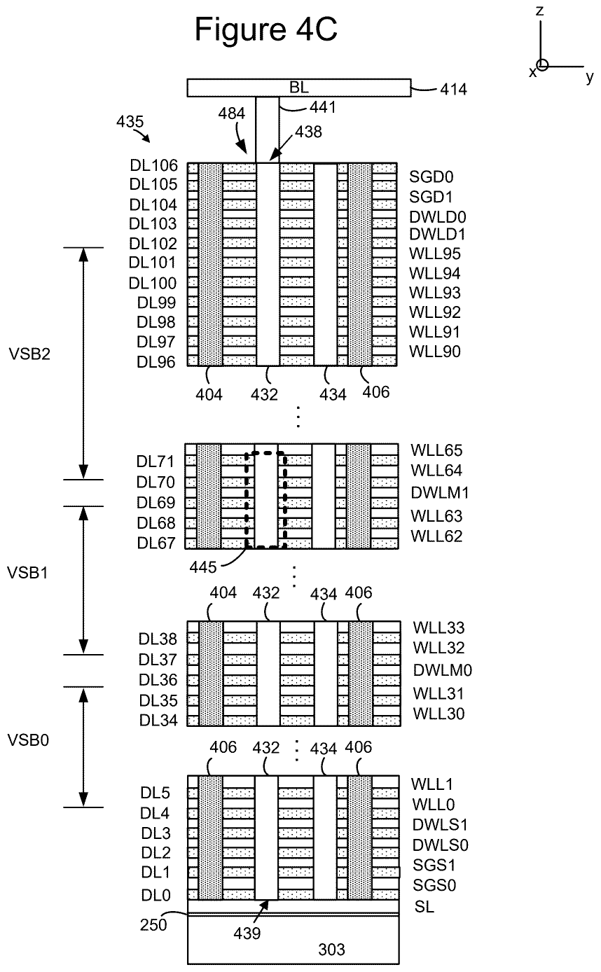

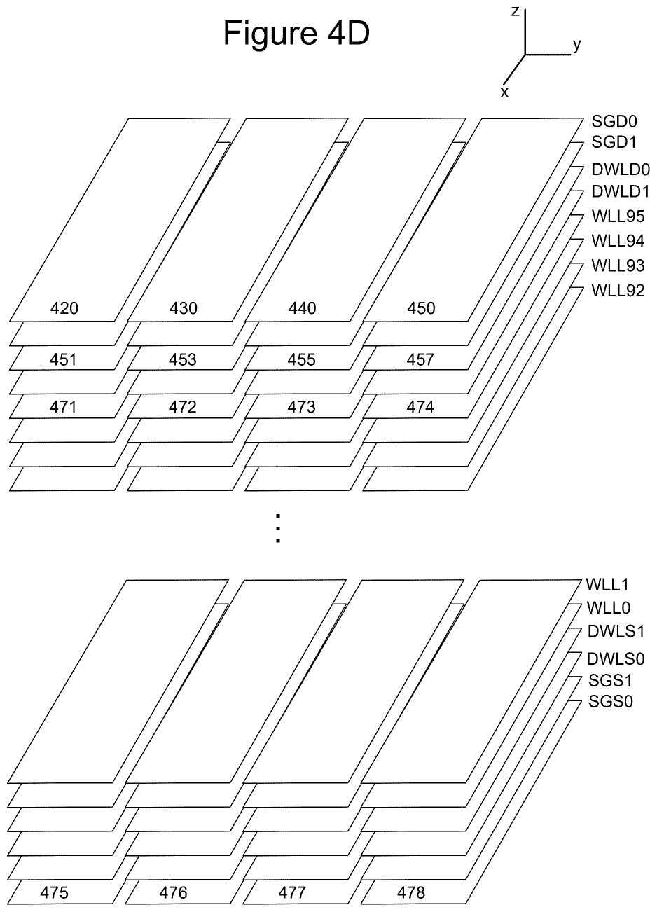

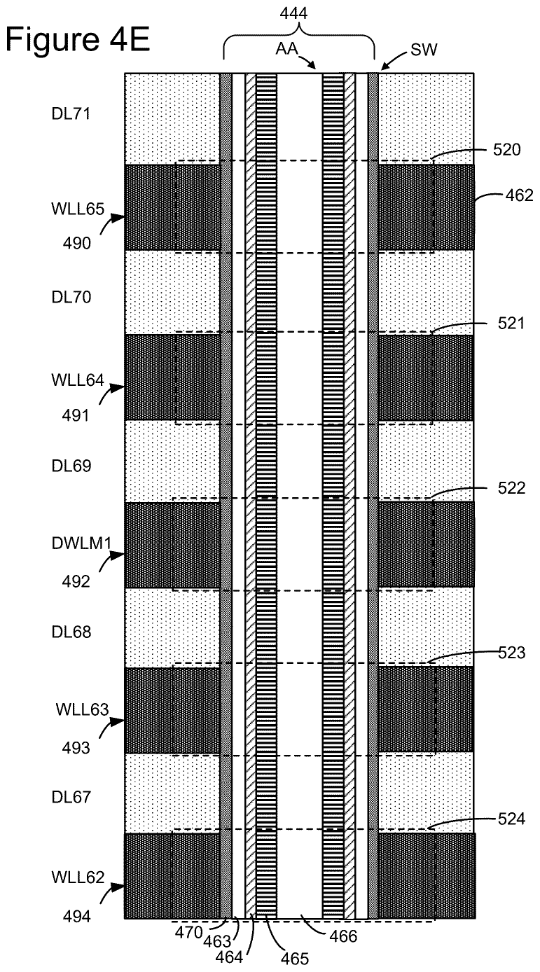

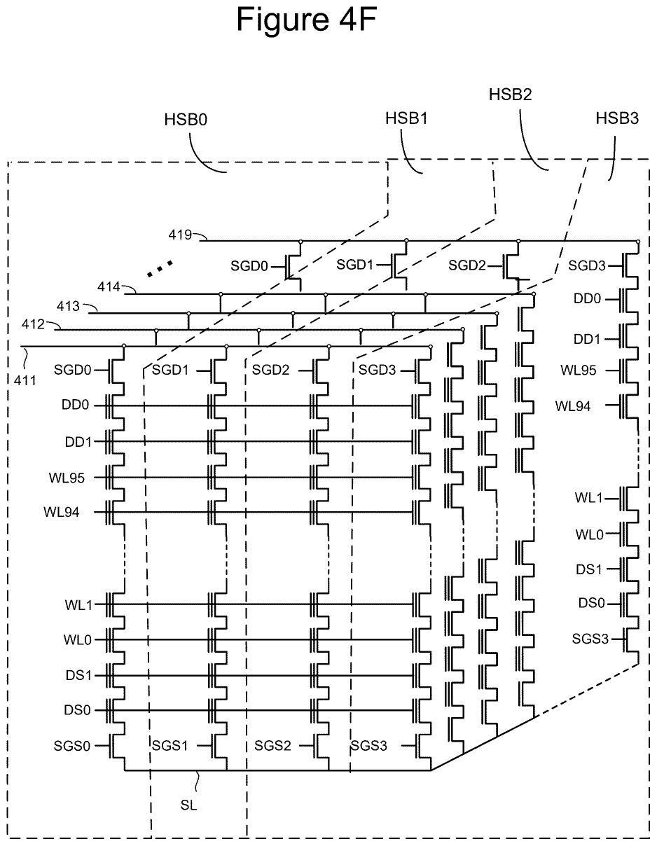

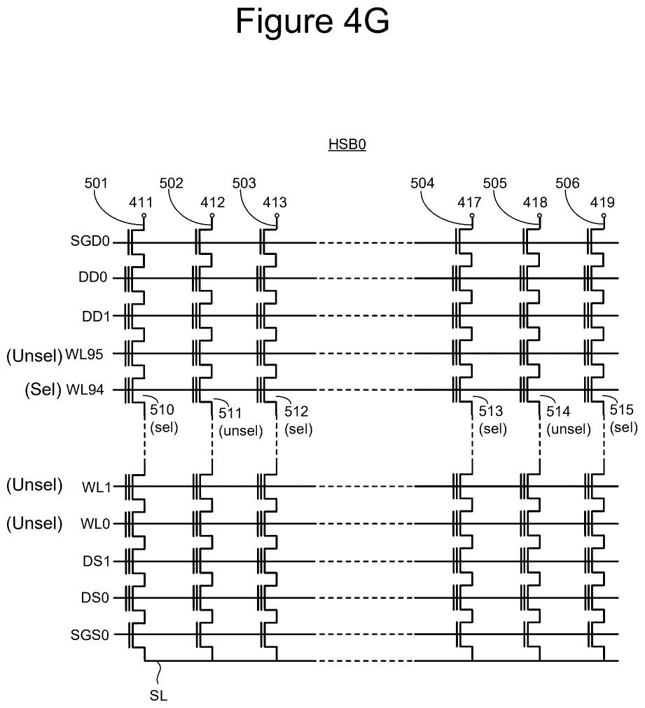

FIG. 4A is a block diagram explaining one example organization of memory structure 202, which is divided into two planes 302 and 304. Each plane is then divided into M blocks. In one example, each plane has about 2000 blocks. However, different numbers of blocks and planes can also be used. In one embodiment, a block of memory cells is a unit of erase. That is, all memory cells of a block are erased together. In other embodiments, memory cells can be grouped into blocks for other reasons, such as to organize the memory structure 202 to enable the signaling and selection circuits. In some embodiments, a block represents a groups of connected memory cells as the memory cells of a block share a common set of word lines.

FIGS. 4B-4F depict an example three dimensional (“3D”) NAND structure that corresponds to the structure of FIG. 3 and can be used to implement memory structure 202 of FIG. 2A or 2B. FIG. 4B is a block diagram depicting a top view of a portion of one block from memory structure 202. The portion of the block depicted in FIG. 4B corresponds to portion 306 in block 2 of FIG. 4A. In one embodiment, the memory array has many layers; however, FIG. 4B only shows the top layer.

FIG. 4B depicts a plurality of circles that represent the vertical columns. Each of the vertical columns include multiple select transistors (also referred to as a select gate or selection gate) and multiple memory cells. In one embodiment, each vertical column implements a NAND string. For example, FIG. 4B depicts vertical columns 422, 432, 442 and 452. Vertical column 422 implements NAND string 482. Vertical column 432 implements NAND string 484. Vertical column 442 implements NAND string 486. Vertical column 452 implements NAND string 488. More details of the vertical columns are provided below. Since the block depicted in FIG. 4B extends beyond the portion shown, the block includes more vertical columns than depicted in FIG. 4B.

FIG. 4B also depicts a set of bit lines 415, including bit lines 411, 412, 413, 414, . . . 419. FIG. 4B shows twenty-four bit lines because only a portion of the block is depicted. It is contemplated that more than twenty-four bit lines connected to vertical columns of the block. Each of the circles representing vertical columns has an “x” to indicate its connection to one bit line. For example, bit line 414 is connected to vertical columns 422, 432, 442 and 452.

The block depicted in FIG. 4B includes a set of local interconnects 402, 404, 406, 408 and 410 that connect the various layers to a source line below the vertical columns. Local interconnects 402, 404, 406, 408 and 410 also serve to divide each layer of the block into four regions; for example, the top layer depicted in FIG. 4B is divided into regions 420, 430, 440 and 450, which are referred to as fingers. In the layers of the block that implement memory cells, the four regions are referred to as word line fingers that are separated by the local interconnects. In one embodiment, the word line fingers on a common level of a block connect together to form a single word line. In another embodiment, the word line fingers on the same level are not connected together. In one example implementation, a bit line only connects to one vertical column in each of regions 420, 430, 440 and 450. In that implementation, each block has sixteen rows of active columns and each bit line connects to four rows in each block. In one embodiment, all of four rows connected to a common bit line are connected to the same word line (via different word line fingers on the same level that are connected together); therefore, the system uses the source side selection lines and the drain side selection lines to choose one (or another subset) of the four to be subjected to a memory operation (program, verify, read, and/or erase).

Although FIG. 4B shows each region having four rows of vertical columns, four regions and sixteen rows of vertical columns in a block, those exact numbers are an example implementation. Other embodiments may include more or less regions per block, more or less rows of vertical columns per region and more or less rows of vertical columns per block.

FIG. 4B also shows the vertical columns being staggered. In other embodiments, different patterns of staggering can be used. In some embodiments, the vertical columns are not staggered.

FIG. 4C depicts an embodiment of a stack 435 showing a cross-sectional view along line AA of FIG. 4B. Two SGD layers (SGD0, SDG1), two SGS layers (SGS0, SGS1) and six dummy word line layers DWLD0, DWLD1, DWLM1, DWLM0, DWLS0 and DWLS1 are provided, in addition to the data word line layers WLL0-WLL95. Each NAND string has a drain side select transistor at the SGD0 layer and a drain side select transistor at the SGD1 layer. In operation, the same voltage may be applied to each layer (SGD0, SGD1), such that the control terminal of each transistor receives the same voltage. Each NAND string has a source side select transistor at the SGS0 layer and a drain side select transistor at the SGS1 layer. In operation, the same voltage may be applied to each layer (SGS0, SGS1), such that the control terminal of each transistor receives the same voltage. Also depicted are dielectric layers DL0-DL106.

Columns 432, 434 of memory cells are depicted in the multi-layer stack. The stack includes a substrate 303, an insulating film 250 on the substrate, and a portion of a source line SL. A portion of the bit line 414 is also depicted. Note that NAND string 484 is connected to the bit line 414. NAND string 484 has a source-end 439 at a bottom of the stack and a drain-end 438 at a top of the stack. The source-end 439 is connected to the source line SL. A conductive via 441 connects the drain-end 438 of NAND string 484 to the bit line 414. The local interconnects 404 and 406 from FIG. 4B are also depicted.

The stack 435 is divided into three vertical sub-blocks (VSB0, VSB1, VSB2). Vertical sub-block VSB0 includes WLL0-WLL31. The following layers could also be considered to be a part of vertical sub-block VSB0 (SGS0, SGS1, DWLS0, DWLS1). Vertical sub-block VSB1 includes WLL32-WLL63. Vertical sub-block VSB2 includes WLL64-WLL95. The following layers could also be considered to be a part of vertical sub-block VSB2 (SGD0, SGD1, DWLD0, DWLD1). Each NAND string has a set of data memory cells in each of the vertical sub-blocks. Dummy word line layer DMLM0 is between vertical sub-block VSB0 and vertical sub-block VSB1. Dummy word line layer DMLM1 is between vertical sub-block VSB1 and vertical sub-block VSB2. The dummy word line layers have dummy memory cell transistors that may be used to electrically isolate a first set of memory cell transistors within the memory string (e.g., corresponding with vertical sub-block VSB0 word lines WLL0-WLL31) from a second set of memory cell transistors within the memory string (e.g., corresponding with the vertical sub-block VSB1 word lines WLL32-WLL63) during a memory operation (e.g., an erase operation or a programming operation).

FIG. 4D depicts an alternative view of the SG layers and word line layers of the stack 435 of FIG. 4C. The SGD layers SGD0 and SGD1 (the drain-side SG layers) each includes parallel rows of SG lines associated with the drain-side of a set of NAND strings. For example, SGD0 includes drain-side SG regions 420, 430, 440 and 450, consistent with FIG. 4B.

Below the SGD layers are the drain-side dummy word line layers. Each dummy word line layer represents a word line, in one approach, and is connected to a set of dummy memory cells at a given height in the stack. For example, DWLD0 comprises word line layer regions 451, 453, 455 and 457. A dummy memory cell, also referred to as a non-data memory cell, does not store data and is ineligible to store data, while a data memory cell is eligible to store data. Moreover, the Vth of a dummy memory cell is generally fixed at the time of manufacture or may be periodically adjusted, while the Vth of the data memory cells changes more frequently, e.g., during erase and programming operations of the data memory cells.

Below the dummy word line layers are the data word line layers. For example, WLL95 comprises word line layer regions 471, 472, 473 and 474.

Below the data word line layers are the source-side dummy word line layers.

Below the source-side dummy word line layers are the SGS layers. The SGS layers SGS0 and SGS1 (the source-side SG layers) each includes parallel rows of SG lines associated with the source-side of a set of NAND strings. For example, SGS0 includes source-side SG lines 475, 476, 477 and 478. Each SG line can be independently controlled, in one approach. Or the SG lines can be connected and commonly controlled.

FIG. 4E depicts a view of the region 445 of FIG. 4C. Data memory cell transistors 520 and 521 are above dummy memory cell transistor 522. Below dummy memory cell transistor 522 are data memory cell transistors 523 and 524. A number of layers can be deposited along the sidewall (SW) of the memory hole 444 and/or within each word line layer, e.g., using atomic layer deposition. For example, each column (e.g., the pillar which is formed by the materials within a memory hole) can include a blocking oxide/block high-k material 470, charge-trapping layer or film 463 such as SiN or other nitride, a tunneling layer 464, a polysilicon body or channel 465, and a dielectric core 466. A word line layer can include a conductive metal 462 such as Tungsten as a control gate. For example, control gates 490, 491, 492, 493 and 494 are provided. In this example, all of the layers except the metal are provided in the memory hole. In other approaches, some of the layers can be in the control gate layer. Additional pillars are similarly formed in the different memory holes. A pillar can form a columnar active area (AA) of a NAND string.

When a data memory cell transistor is programmed, electrons are stored in a portion of the charge-trapping layer which is associated with the data memory cell transistor. These electrons are drawn into the charge-trapping layer from the channel, and through the tunneling layer. The Vth of a data memory cell transistor is increased in proportion to the amount of stored charge. During an erase operation, the electrons return to the channel.

Non-data transistors (e.g., select transistors, dummy memory cell transistors) may also include the charge trapping layer 463. In FIG. 4E, dummy memory cell transistor 522 includes the charge trapping layer 463. Thus, the threshold voltage of at least some non-data transistors may also be adjusted by storing or removing electrons from the charge trapping layer 463. It is not required that all non-data transistors have an adjustable Vth. For example, the charge trapping layer 463 is not required to be present in every select transistor.

Each of the memory holes can be filled with a plurality of annular layers comprising a blocking oxide layer, a charge trapping layer, a tunneling layer and a channel layer. A core region of each of the memory holes is filled with a body material, and the plurality of annular layers are between the core region and the WLLs in each of the memory holes.

In some cases, the tunneling layer 464 can comprise multiple layers such as in an oxide-nitride-oxide configuration.

FIG. 4F is a schematic diagram of a portion of the memory depicted in in FIGS. 3-4E. FIG. 4F shows physical word lines WLL0-WLL95 running across the entire block. The structure of FIG. 4F corresponds to portion 306 in Block 2 of FIGS. 4A-E, including bit lines 411, 412, 413, 414, . . . 419. Within the block, each bit line is connected to four NAND strings. Drain side selection lines SGD0, SGD1, SGD2 and SGD3 are used to determine which of the four NAND strings connect to the associated bit line(s). Source side selection lines SGS0, SGS1, SGS2 and SGS3 are used to determine which of the four NAND strings connect to the common source line. The block can also be thought of as divided into four horizontal sub-blocks HSB0, HSB1, HSB2 and HSB3. Horizontal sub-block HSB0 corresponds to those vertical NAND strings controlled by SGD0 and SGS0, Horizontal sub-block HSB1 corresponds to those vertical NAND strings controlled by SGD1 and SGS1, Horizontal sub-block HSB2 corresponds to those vertical NAND strings controlled by SGD2 and SGS2, and Horizontal sub-block HSB3 corresponds to those vertical NAND strings controlled by SGD3 and SGS3.

FIG. 4G is a schematic of horizontal sub-block HSB0. Horizontal sub-blocks HSB1, HSB2 and HSB3 have similar structures. FIG. 4G shows physical word lines WL0-WL95 running across the entire sub-block S0. All of the NAND strings of sub-block S0 are connected to SGD0 and SGS0. FIG. 4G only depicts six NAND stings 501, 502, 503, 504, 505 and 506; however, horizontal sub-block HSB0 will have thousands of NAND strings (e.g., 15,000 or more).

FIG. 4G is being used to explain the concept of a selected memory cell. A memory access operation (memory operation) is an operation designed to use the memory for its purpose and includes one or more of reading data, writing/programming data, erasing memory cells, refreshing data in memory cells, and the like. During any given memory operation, a subset of the memory cells will be identified to be subjected to one or more parts of the memory operation. These memory cells identified to be subjected to the memory operation are referred to as selected memory cells. Memory cells that have not been identified to be subjected to the memory operation are referred to as unselected memory cells. Depending on the memory architecture, the memory type, and the memory operation, unselected memory cells may be actively or passively excluded from being subjected to the memory operation.

As an example of selected memory cells and unselected memory cells, during a programming process, the set of memory cells intended to take on a new electrical characteristic (or other characteristic) to reflect a changed programming state are referred to as the selected memory cells while the memory cells that are not intended to take on a new electrical characteristic (or other characteristic) to reflect a changed programming state are referred to as the unselected memory cells. In certain situations, unselected memory cells may be connected to the same word line as selected memory cells. Unselected memory cells may also be connected to different word lines than selected memory cells. Similarly, during a reading process, the set of memory cells to be read are referred to as the selected memory cells while the memory cells that are not intended to be read are referred to as the unselected memory cells.

To better understand the concept of selected memory cells and unselected memory cells, assume a programming operation is to be performed and, for example purposes only, that word line WL94 and horizontal sub-block HSB0 are selected for programming (see FIG. 4G). That means that all of the memory cells connected to WL94 that are in horizontal sub-blocks HSB1, HSB2 and HSB3 (the other horizontal sub-blocks) are unselected memory cells. Some of the memory cells connected to WL94 in horizontal sub-block HS0 are selected memory cells and some of the memory cells connected to WL94 in horizontal sub-block HS0 are unselected memory cells depending on how the programming operation is performed and the data pattern being programmed. For example, those memory cells that are to remain in the erased state S0 will be unselected memory cells, because their programming state will not change in order to store the desired data pattern, while those memory cells that are intended to take on a new electrical characteristic (or other characteristic) to reflect a changed programming state (e.g., programmed to states S1-S7) are selected memory cells. Looking at FIG. 4G, assume for example purposes, that memory cells 511 and 514 (which are connected to word line WL94) are to remain in the erased state; therefore, memory cells 511 and 514 are unselected memory cells (labeled “unsel” in FIG. 4G). Additionally, assume for example purposes that memory cells 510, 512, 513 and 515 (which are connected to word line WL94) are to be programmed to any of the data states S1-S7; therefore, memory cells 510, 512, 513 and 515 are selected memory cells (labeled “sel” in FIG. 4G). While some memory cells along WL94 may be considered unselected memory cells because they are to remain in the erased state, WL94 may be considered as a “selected word line” in this scenario because selected memory cells 510, 512, 513 and 515 are connected to WL94 and are accessed via WL94.

Although the example memory system of FIGS. 3-4G is a three dimensional memory structure that includes vertical NAND strings with charge-trapping material, other (2D and 3D) memory structures can also be used with the technology described herein. Different operations for accessing data in non-volatile memory cells (e.g., read, program, program verify) that are described below may be applied to one or more of the example memory systems described above with respect to FIGS. 3-4G.

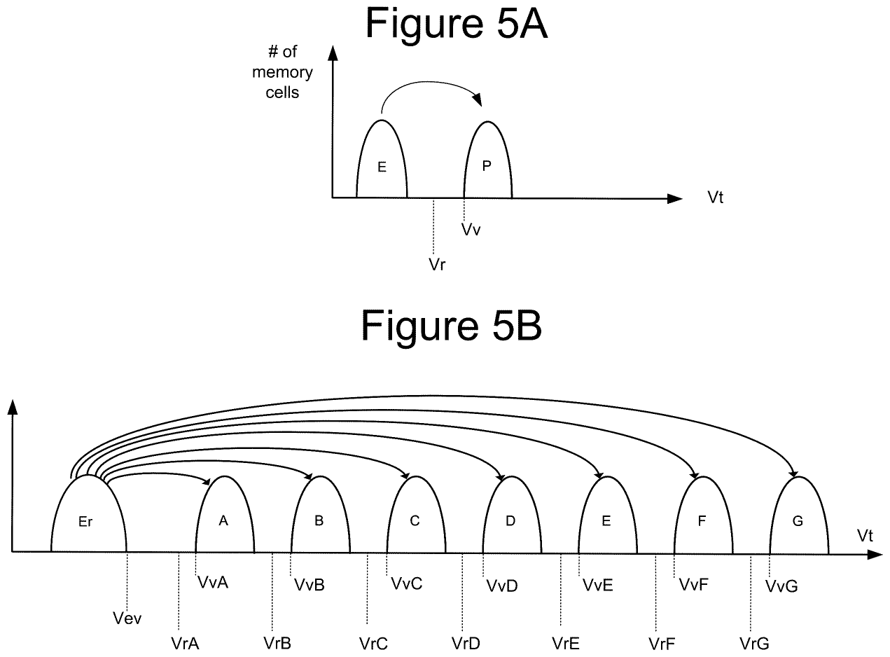

Memory cells in a memory system may be erased, programmed and read in corresponding operations (e.g., erase operation, program operation and read operation respectively, which may considered examples of memory access operations). At the end of a successful programming process, the threshold voltages of the memory cells should be within one or more distributions of threshold voltages for programmed memory cells or within a distribution of threshold voltages for erased memory cells, as appropriate. FIG. 5A is a graph of threshold voltage versus number of memory cells, which illustrates example threshold voltage distributions for the memory array when each memory cell stores one bit of data per memory cell. Memory cells that store one bit of data per memory cell data are referred to as single level cells (“SLC”). The data stored in SLC memory cells is referred to as SLC data; therefore, SLC data comprises one bit per memory cell. Data stored as one bit per memory cell is SLC data. FIG. 5A shows two threshold voltage distributions: E and P. Threshold voltage distribution E corresponds to an erased data state. Threshold voltage distribution P corresponds to a programmed data state. Memory cells that have threshold voltages in threshold voltage distribution E are, therefore, in the erased data state (e.g., they are erased). Memory cells that have threshold voltages in threshold voltage distribution P are, therefore, in the programmed data state (e.g., they are programmed). In one embodiment, erased memory cells store data “1” and programmed memory cells store data “0.” FIG. 5A depicts read reference voltage Vr. By testing (e.g., performing one or more sense operations) whether the threshold voltage of a given memory cell is above or below Vr, the system can determine whether a memory cells is erased (state E) or programmed (state P). FIG. 5A also depicts verify reference voltage Vv. In some embodiments, when programming memory cells to data state P, the system will test whether those memory cells have a threshold voltage greater than or equal to Vv in a program-verify (or “verify”) operation. In some embodiments, verify is not performed during SLC programming.

Memory cells that are configured to store multiple bit per memory cell data are referred to as multi-level cells (“MLC”). The data stored in MLC memory cells is referred to as MLC data; therefore, MLC data comprises multiple bits per memory cell. Data stored as multiple bits of data per memory cell is MLC data. In the example embodiment of FIG. 5B, each memory cell stores three bits of data. Other embodiments may use other data capacities per memory cell (e.g., such as two, four, or five bits of data per memory cell). Memory cells may be configured for SLC or MLC storage of data. In some cases, a block of nonvolatile memory cells may be configured for SLC data storage at one time and configured for MLC data storage at another time.

FIG. 5B shows eight threshold voltage distributions, corresponding to eight data states that stores three bits per cell. The first threshold voltage distribution (data state) Er represents memory cells that are erased. The other seven threshold voltage distributions (data states) A-G represent memory cells that are programmed and, therefore, are also called programmed states. Each threshold voltage distribution (data state) corresponds to predetermined values for the set of data bits. The specific relationship between the data programmed into the memory cell and the threshold voltage levels of the cell depends upon the data encoding scheme adopted for the cells. In one embodiment, data values are assigned to the threshold voltage ranges using a Gray code assignment so that if the threshold voltage of a memory erroneously shifts to its neighboring physical state, only one bit will be affected. In an embodiment, the number of memory cells in each state is about the same.

FIG. 5B shows seven read reference voltages, VrA, VrB, VrC, VrD, VrE, VrF, and VrG for reading data from memory cells. By testing (e.g., performing sensing in a read or program verify operation) whether the threshold voltage of a given memory cell is above or below the seven read reference voltages, the system can determine what data state (i.e., A, B, C, D, . . . ) a memory cell is in. FIG. 5B also shows a number of verify reference voltages. The verify voltages are VvA, VvB, VvC, VvD, VvE, VvF, and VvG. In some embodiments, when programming memory cells to data state A, the system will test whether those memory cells have a threshold voltage greater than or equal to VvA. If the memory cell has a threshold voltage greater than or equal to VvA, then the memory cell is inhibited (locked out) from further programming. Similar reasoning applies to the other data states. In some embodiments, verify is not performed during MLC programming.

Each memory cell programmed according to the scheme illustrated in FIG. 5B, using 8 data states, may store 3 bits of data with each bit associated with a logical page. A read operation may be directed to one or more logical pages of data. Read operations directed to different logical pages may perform reads at different read voltages (e.g., it may not be necessary to perform read steps at all read voltages shown in response to a read request directed to only one or two of the logical pages stored).

While FIGS. 5A-B show threshold voltage distributions as distinct distributions that are separated from each other, real threshold voltage distributions may not be separated as shown (e.g., a distribution may partially overlap one or more neighboring distributions), which may make distinguishing different threshold voltage distributions more challenging. Also, threshold voltage distributions may not be identical across all nonvolatile memory cells of a memory die over time and under different conditions. Threshold voltage distributions may shift for a number of reasons including environmental reasons (e.g., temperature or other external parameter), leakage, effects of programming or erasing neighboring memory cells and effects of read operations on cells being read and/or neighboring cells, which may add to the difficulty of accurately distinguishing different threshold voltage distributions (e.g., when reading nonvolatile memory cells to determine corresponding data states). As the number of data states increases, the threshold voltage ranges for each data state become narrower which may increase overlap of neighboring distributions and provide additional challenges when performing read operations.

During memory access operations (e.g., read, write and erase operations), various memory access voltages may be applied to components of a memory structure (e.g., word lines, bit lines and select gates). For example, drivers (e.g., array drivers 224 in row control circuitry 220 and driver circuits 214 in column control circuitry 210) may generate appropriate memory access voltages according to memory access operations and may apply the memory access voltages on respective components.

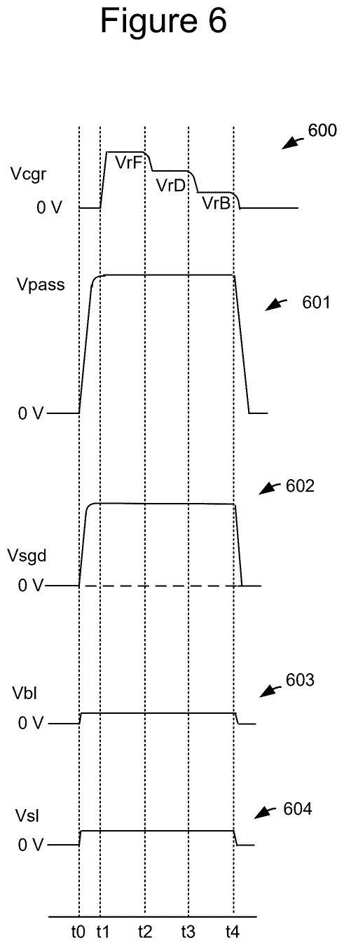

FIG. 6 illustrates example memory access voltages including voltage signals (plots 600-604) for performing a read operation. The voltage 600 depicts Vcgr, the voltage applied to control gates of the selected memory cells via the selected word line, WLn, to perform reads at three different read voltages (e.g., to obtain one logical page of data). The control gate voltage, Vcgr, for reading is set to VrF, VrD and VrB. Sensing occurs during each value of Vcgr to determine the data of the logical page. Voltage 601 denotes the read pass voltages (Vpass) applied to the unselected word lines (e.g., WL0 to WLn−1 and WLn+1 to WL95). Vsgd denotes the SGD voltage 602 and is set at a high level provided to selected SGD transistors (e.g., SGD0) in a conductive state. Vbl 603 denotes the bit line voltage applied on bit lines such as bit lines 411 to 419 and is set at a level such as 0.5 V as part of the sensing process. Vsl 604 denotes the source line voltage applied to SL and can be set at a small positive voltage, in one approach.

At time t0, unselected word line voltage 601, Vsgd 602, Vbl 603 and Vsl 604 are ramped up to respective target voltages. Subsequently, at time t1, the selected word line voltage, Vcgr 600, is ramped up to a first read voltage VrF and a first read step is performed to identify which memory cells are on/off with VrF applied to their control gates. Subsequently, at time t2, the selected word line voltage, Vcgr 600, is ramped down to a second read voltage, VrD, and a second read step is performed to identify which memory cells are on/off with VrD applied to their control gates. Subsequently, at time t3, the selected word line voltage, Vcgr 600, is ramped down to a third read voltage, VrB, and a third read step is performed to identify which memory cells are on/off with VrB applied to their control gates. Subsequently, at time t4, the selected word line voltage, Vcgr 600, is ramped down to a post-read voltage (e.g., 0 volts). While the example of FIG. 6 shows a sequence of three different read voltages to read one logical page, in other examples, other sequences with different numbers of read voltages may be used. The present technology is not limited to any particular scheme of applying read voltages.

When memory access voltages deviate significantly from their target ranges (e.g., from a predetermined voltage range for a given operation such as Vpass), this may affect the accuracy of a memory access operation. For example, where the read operation of FIG. 6 requires a predetermined voltage (e.g., 6.0 volts) or voltage range (e.g., 5.9 volts to 6.1 volts) for Vpass, deviation from the predetermined voltage or voltage range may impact accuracy of the read operation and may result in an increase in errors in output data. Similarly, deviation of memory access voltages from predetermined voltage ranges in other memory access operations may impact those operations. While a read operation may be used as an example of a memory access operation that may be carried out using aspects of the present technology, other memory access operations may be carried out using aspects of the present technology, which is not limited to any particular memory access operation or memory access voltage(s).

Examples of deviations from a predetermined range that may occur in memory access voltages include overshoot, undershoot and droop. As loads change (e.g., as a memory access voltage is turned on or off for memory structure components) it may take some time for the memory access voltage to stabilize (e.g., a voltage may drop or rise until it returns to a predetermined voltage range). The recovery time (slew time) after such a change may affect the total time for an operation (e.g., a wait time for stabilization) and/or may impact the operation (e.g., affect error rate of a read operation). Uniformity of memory access voltages and slew times across a die and/or from die-to-die may be desirable so that, for example, error rates are uniform. Reducing power consumption used in memory access operations may be important in some cases (e.g., mobile applications where power is limited).

Aspects of the present technology are directed to circuits and methods for providing memory access voltage(s) within acceptable limits. For example, overshoot, droop and/or slew may be managed so that they do not significantly impact memory access operations, which may be completed in an acceptable time and without using excessive power. Aspects of the present technology are directed to technical problems of controlling memory access voltages provided to memory structure components (e.g., word lines, bit lines and select gates). Aspects of the present technology provide technical solutions that include, for example, circuits and methods to discharge an output terminal efficiently, which may mitigate overshoot.

While examples are described with respect to pass voltages Vpass (e.g., read pass and write pass voltages), applied to unselected word lines in read and write operations, the present technology may be applied to any memory access voltage applied to any memory structure component during any operation. And while examples are described with respect to mitigation of voltage overshoot, aspects of the present technology may have other and/or additional benefits and the present technology is not limited to mitigation of voltage overshoot.

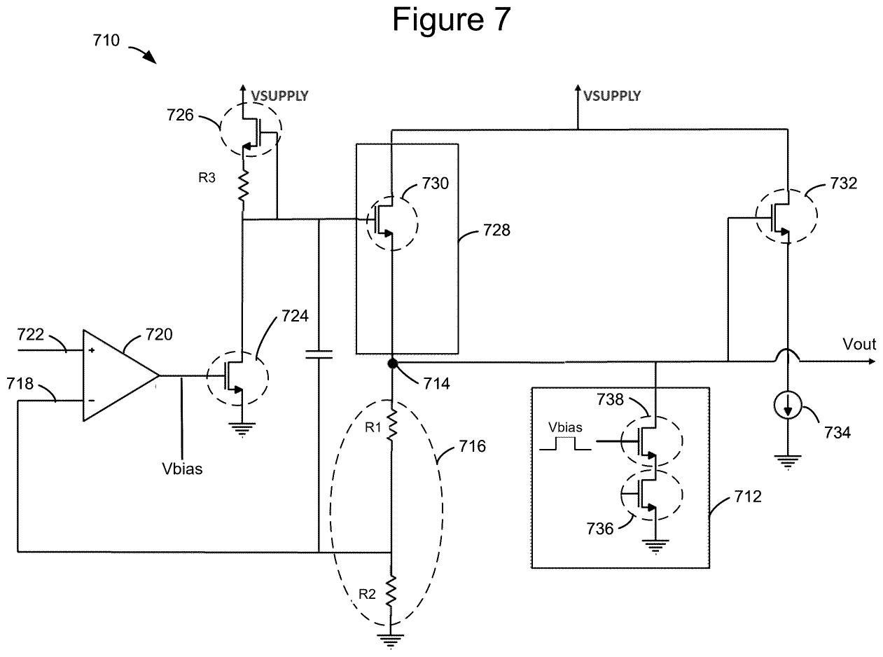

FIG. 7 shows an example of control circuits that may be used to provide an output voltage (e.g., a memory access voltage) including a driver circuit 710 with a voltage discharger 712 connected to an output node 714. In this example, a voltage divider 716 formed of two resistors, R1 and R2, provides an analog feedback signal (indicator signal) to a first input terminal 718 of an amplifier 720, which receives a reference voltage (e.g., Vref) on a second input terminal 722. The output of amplifier 720 may increase according to the difference between the analog feedback signal and the reference voltage. The output of amplifier 720 (Vbias) controls a second stage driver 724 (NMOS device or transistor), which is connected in series with a resistor, R3, and another driver 724 (NMOS device or transistor) between a supply voltage (“VSUPPLY”) and ground. A gate voltage is provided from between second stage driver 724 and resistor R3 to output stage 728. Output stage 728 includes a driver 730 (NMOS device or transistor) and may be considered a class A output stage. Output stage 728 is connected in series with voltage divider 716 between supply voltage VSUPPLY and ground. Node 714 between output stage 728 and voltage divider 716 provides an output voltage (“Vout”) of driver 710 and may be considered an output node. Another switch 732 (NMOS switch or transistor) is connected in series with a current source 734 between VSUPPLY and ground, with switch 732 controlled by Vout.

Voltage discharger 712 is connected to output node 714 to enable a discharge current from output node 714 under certain conditions. Voltage discharger 712 includes two switches (NMOS devices or transistors), enable switch 736, which may be turned on by logic circuits during a memory access operation, and discharge switch 738, which receives Vbias from amplifier 720. Vbias may be an analog signal (e.g., voltage may be from low to high to turn discharge switch 738 on/off). For example, when voltage at first input terminal 718 (from voltage divider 716) is above voltage at second terminal 722 (e.g., Vref), Vbias may change from low to high to turn on discharge switch 738 and enable discharge of output node 714. This may be used to manage voltage overshoot.

While the control circuits of FIG. 7 may be used to control a memory access voltage (e.g., a pass voltage applied on nonselected word lines), significant overshoot may occur before voltage discharger 712 causes voltage to return to an acceptable voltage range and the time to recover may be significant.

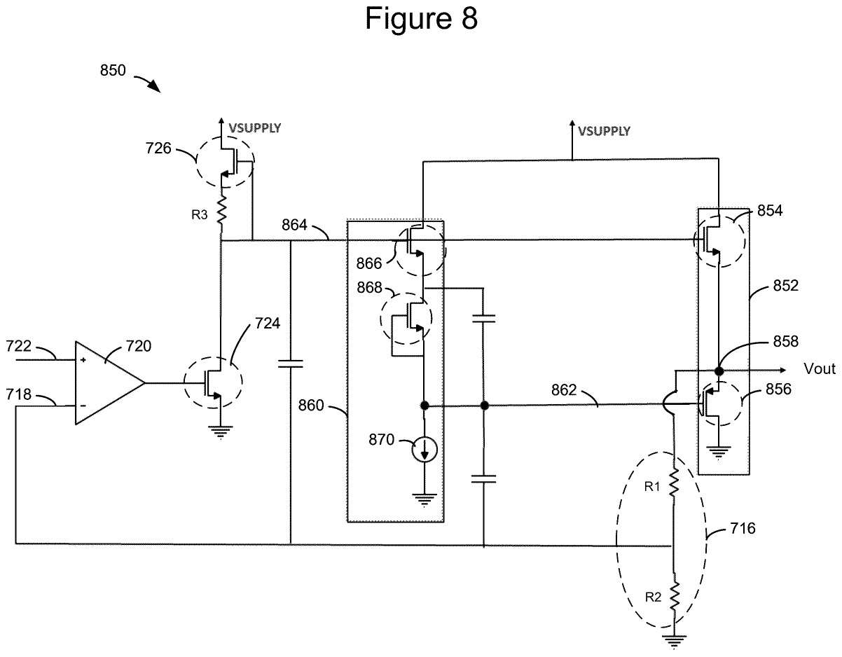

FIG. 8 shows an example of control circuits 850 configured to generate an output voltage Vout (e.g., apply a memory access voltage such as Vpass on a word line) according to an example of the present technology. For example, control circuits 850 may be located in array drivers 224. Certain components of control circuits 850 which are similar to those shown in FIG. 7 are similarly labeled and are not discussed further in detail here.

Control circuits 850 include voltage divider 716 connected to provide an indicator signal (according to voltage at output node 858) on first input terminal 718 of amplifier 720. Amplifier 720 receives a reference voltage (e.g., Vref) on a second input terminal 722 and controls driver 724 (NMOS device or transistor) connected in series with resistor, R3, and driver 726 (NMOS device or transistor) between VSUPPLY and ground as before.

In contrast to control circuits 710, control circuits 850 include an output stage 852, which includes a first switch 854, which is implemented by an NMOS device (transistor), and a second switch 856, which is implemented by a PMOS device (transistor). Output node 858 is located between first switch 854 and second switch 856 and outputs an output voltage, Vout, (e.g., a predetermined voltage such as a memory access voltage which may be applied to a memory structure component (e.g., word line) in a memory access operation). First switch 854 is configured to provide current at output node 858. Second switch 856 is configured to sink or discharge current from output node 858. Output stage 852 may be considered a push-pull output stage (e.g., it includes a device to pull voltage down and a device to push voltage up) sometimes referred to as a modified class-AB output stage.

Second switch 856 provides a discharge pathway connected to output terminal 858 to enable discharge when a voltage at output terminal 858 exceeds a limit (e.g., when voltage overshoot occurs). Second switch 856 is controlled by an analog control signal from bias circuit 860, which is connected to the gate of second switch 856 by a conductive line 862. The analog control signal on line 862 allows a current through second switch 856 (e.g., a discharge current between output terminal 858 and ground) to be controlled proportionally (e.g., proportional to overshoot). For example, the output of amplifier 720 may be proportional to the difference between a voltage from voltage divider 716, which is received at first terminal 718, and a reference voltage at second input terminal 722 so that discharge current increases in proportion to the difference (e.g. proportional to voltage overshoot at output node 858). Driver 724 is controlled by the output of amplifier 720 and Driver 724 provides a gate signal to bias circuit 860 via conductive line 864.

Bias circuit 860 includes a first NMOS device 866, a second NMOS device 868 and a current source 870 connected in series between a supply voltage, VSUPPLY, and ground with an output for the analog control signal (on line 862) located between second NMOS device 868 and current source 870. The gate terminal of first NMOS device 866 receives a gate signal on conductive line 864 according to a difference between an indicator signal from voltage divider 716 and a predetermined voltage (e.g., via amplifier 720 and Driver 724). Bias circuit 860 generates an analog control signal on line 862 that may be a function of the voltage difference at input terminals 718 and 722 of amplifier 720. The analog control signal on line 862 controls the discharge pathway formed by switch 856 such that discharge current between output node 858 and ground increases according to the difference between the analog feedback signal and the reference voltage.

Conductive line 864 is also connected to switch 854 (e.g., to gate of NMOS device) to control current flowing from VSUPPLY to output node 858 (e.g., to charge up a word line to a predetermined voltage for a memory access operation).

When output terminal 858 is connected to a memory structure component (e.g., unselected word line) during a memory access operation (e.g., read) control circuits 850 may provide a memory access voltage (e.g., pass voltage, Vpass) with limited overshoot because of discharge in output stage 852. Control circuits 850, output stage 852, device 856 (e.g., in combination with one or more other circuits) may be considered examples of means for applying a pass voltage on one or more unselected word lines in a read or write operation directed to a plurality of nonvolatile memory cells and limiting overshoot of the pass voltage by controlling a discharge current from an output terminal according to an analog control signal where the discharge current is proportional to the overshoot of the pass voltage.

Benefits of the present technology may include, but are not limited to, reduced overshoot, reduced recovery time (e.g., after overshoot or other instability occurs), more uniformity and reduced droop.

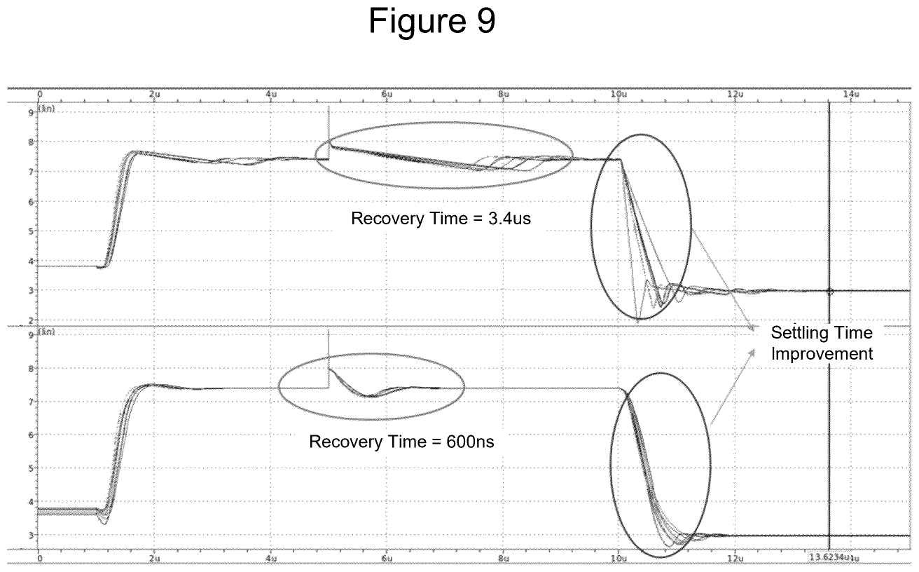

FIG. 9 shows a comparison of output voltages of control circuits 850, which use a push-pull output stage (upper plots), with control circuits 710, which do not include a push-pull output stage (lower plots). It can be seen that recovery time from an overshoot is significantly reduced (e.g., from 3.4 us to 600 ns in the example shown). Furthermore, settling time (e.g., when Vout ramps down) is improved (e.g., quicker to reach stability and more uniform).

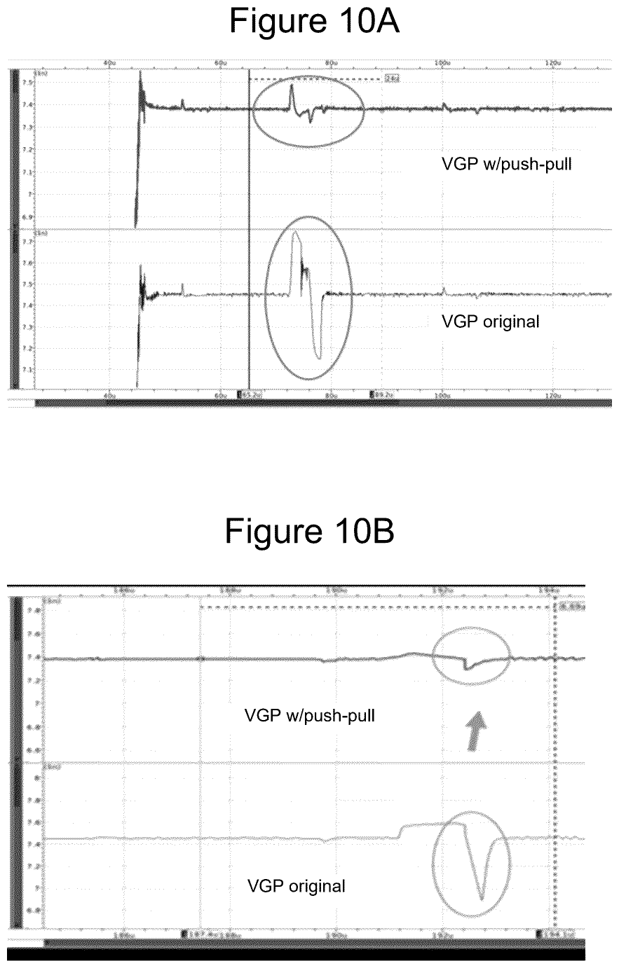

FIGS. 10A-B show two examples of how aspects of the present technology may reduce voltage droop. In both examples, an output voltage from control circuit 850 (VGP with push-pull) is shown above for comparison with an output voltage from a control circuit that does not use a push-pull configuration (VGP Original), for example, as shown in FIG. 7. It can be seen that in both examples, droop is significantly reduced by using a push-pull output stage. For example, droop may be reduced by a factor of three (3×) so that a droop of 300 mV may be reduced to 100 mV with little or no area penalty.

In some examples, because a push-pull output stage (e.g., as shown in FIG. 8) provides faster transient response than alternatives (e.g., as shown in FIG. 7), a limiter current may be reduced while maintaining adequate characteristics, which may allow a reduction in corresponding voltage generators (e.g., in a range from 20% to 30%). Thus, any additional space occupied by control circuits 850 in comparison with alternatives may be offset by space saving from reduced area needed for voltage generators.

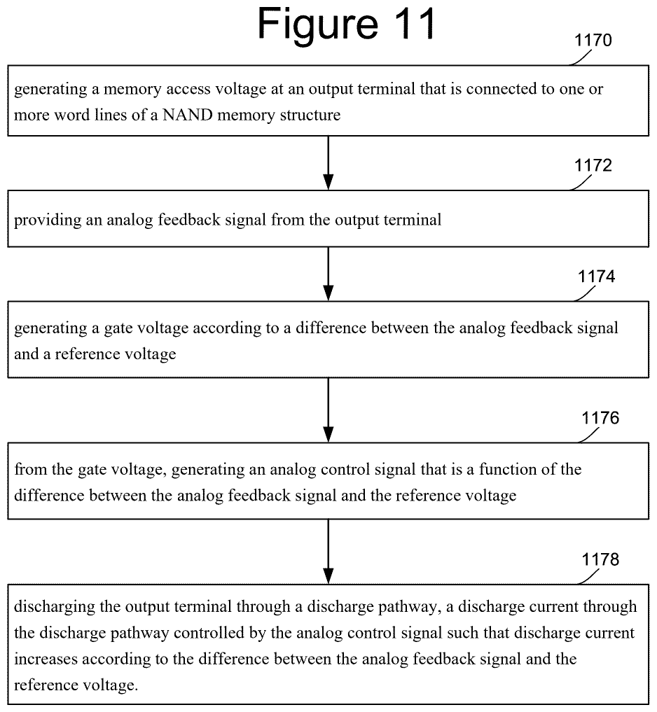

FIG. 11 shows an example of a method, which may be implemented using control circuits 850 or other suitable control circuits. The method includes generating a memory access voltage at an output terminal that is connected to one or more word lines of a NAND memory structure 1170 (e.g., a Vpass voltage for a read operation), providing an analog feedback signal from the output terminal 1172 (e.g., voltage divider 716 providing feedback to first input terminal 718), generating a gate voltage according to a difference between the analog feedback signal and a reference voltage 1174 (e.g., amplifier 720 and Driver 724 generating a gate voltage on line 864) and from the gate voltage, generating an analog control signal that is a function of the difference between the analog feedback signal and the reference voltage 1176 (e.g., bias circuit 860 generating an analog control signal on line 862). The method further includes discharging the output terminal through a discharge pathway, a discharge current through the discharge pathway controlled by the analog control signal such that discharge current increases according to the difference between the analog feedback signal and the reference voltage 1178 (e.g., discharge current controlled by voltage from line 862 on gate of device 856, which is part of the discharge pathway).

According to examples of the present technology, an apparatus includes one or more control circuits configured to connect to a plurality of nonvolatile memory cells. The one or more control circuits are configured to apply a predetermined voltage on one or more word lines connected to the nonvolatile memory cells in a memory access operation and limit overshoot of the predetermined voltage by controlling a discharge pathway at an output terminal according to an analog control signal. The analog control signal is proportional to voltage overshoot of the predetermined voltage.

In one or more embodiments, the discharge pathway is directly connected to the output terminal and controlling the discharge pathway includes controlling a discharge current between the output terminal and a ground terminal.

In one or more embodiments, the discharge pathway is formed by a PMOS device that has a first terminal directly connected to the output terminal, a second terminal directly connected to the ground terminal and a gate that receives the analog control signal.

In one or more embodiments, the apparatus further includes an NMOS device that has a first terminal connected to a supply voltage and a second terminal connected to the first terminal of the PMOS device and to the output terminal to form a push-pull output stage.

In one or more embodiments, the analog control signal is generated by a bias circuit that includes a first NMOS device, a second NMOS device and a current source connected in series between a supply voltage and ground with an output for the analog control signal located between the second NMOS device and the current source.

In one or more embodiments, a gate terminal of the first NMOS device receives a gate signal that is proportional to the overshoot of the predetermined voltage.

In one or more embodiments, the gate signal is generated by a first NMOS device controlled by an output of an amplifier, the amplifier includes a first input terminal connected to receive an indicator signal that indicates voltage at the output terminal, a second input terminal connected to the predetermined voltage, and an output terminal connected to the gate terminal of the first NMOS device.

In one or more embodiments, the first NMOS device, a resistor and a second NMOS device are connected in series between ground and a supply voltage.

In one or more embodiments, the plurality of nonvolatile memory cells are arranged in a 3D NAND structure.

In one or more embodiments, the one or more control circuits are formed on a control die, the plurality of nonvolatile memory cells are formed on a memory die and the control die and memory die are bonded to form an integrated memory assembly.

An example method includes generating a memory access voltage at an output terminal that is connected to one or more word lines of a NAND memory structure; providing an analog feedback signal from the output terminal; generating a gate voltage according to a difference between the analog feedback signal and a reference voltage; from the gate voltage, generating an analog control signal that is a function of the difference between the analog feedback signal and the reference voltage; and discharging the output terminal through a discharge pathway, a discharge current through the discharge pathway controlled by the analog control signal such that discharge current increases according to the difference between the analog feedback signal and the reference voltage.

In one or more embodiments, the discharge pathway is formed by a PMOS device and discharging the output terminal includes applying the analog control signal to a gate terminal of the PMOS device to cause a discharge current that increases in proportion to the difference between the analog feedback signal and the reference voltage.

In one or more embodiments, providing the analog feedback signal from the output terminal includes providing the analog feedback signal from a node of a voltage divider that is connected between the output terminal and ground.

In one or more embodiments, generating the gate voltage includes providing the analog feedback signal and the reference voltage to input terminals of an amplifier such that an output of the amplifier increases according to the difference between the analog feedback signal and the reference voltage.

In one or more embodiments, generating the gate voltage further includes providing the output of the amplifier to a control gate of a first NMOS device that is connected in series with a resistor and a second NMOS device between ground and a supply voltage, the gate voltage generated between the first NMOS device and the resistor.

In one or more embodiments, generating the memory access voltage at the output terminal includes providing the gate voltage to an NMOS device that is connected between a supply voltage and the output terminal, the discharge pathway is formed by a PMOS device and the NMOS device and PMOS device form a push-pull output stage.

In one or more embodiments, the one or more word lines are unselected word lines in a read or write operation, the memory access voltage is a pass voltage and discharging the output terminal mitigates pass voltage overshoot on the unselected word lines.

An example storage system includes a plurality of nonvolatile memory cells connected by word lines; and means for applying a pass voltage on one or more unselected word lines in a read or write operation directed to the plurality of nonvolatile memory cells and limiting overshoot of the pass voltage by controlling a discharge current from an output terminal according to an analog control signal where the discharge current is proportional to the overshoot of the pass voltage.

In one or more embodiments, the plurality of nonvolatile memory cells are arranged in a 3D NAND structure.

In one or more embodiments, the 3D NAND structure is located on a memory die, the means for applying a pass voltage is located on a control die and the control die is bonded to the memory die to form an integrated memory assembly.

For purposes of this document, reference in the specification to “an embodiment,” “one embodiment,” “some embodiments,” or “another embodiment” may be used to describe different embodiments or the same embodiment.

For purposes of this document, a connection may be a direct connection or an indirect connection (e.g., via one or more other parts). In some cases, when an element is referred to as being connected or coupled to another element, the element may be directly connected to the other element or indirectly connected to the other element via one or more intervening elements. When an element is referred to as being directly connected to another element, then there are no intervening elements between the element and the other element. Two devices are “in communication” if they are directly or indirectly connected so that they can communicate electronic signals between them.

For purposes of this document, the term “based on” may be read as “based at least in part on.”

For purposes of this document, without additional context, use of numerical terms such as a “first” object, a “second” object, and a “third” object may not imply an ordering of objects but may instead be used for identification purposes to identify different objects.

For purposes of this document, the term “set” of objects may refer to a “set” of one or more of the objects.

The foregoing detailed description has been presented for purposes of illustration and description. It is not intended to be exhaustive or to limit to the precise form disclosed. Many modifications and variations are possible in light of the above teaching. The described embodiments were chosen in order to best explain the principles of the proposed technology and its practical application, to thereby enable others skilled in the art to best utilize it in various embodiments and with various modifications as are suited to the particular use contemplated. It is intended that the scope be defined by the claims appended hereto.

What is claimed is:

1. An apparatus comprising:
one or more control circuits configured to connect to a plurality of nonvolatile memory cells, wherein the one or more control circuits are configured to:
apply a predetermined voltage on one or more word lines connected to the nonvolatile memory cells in a memory access operation and limit overshoot of the predetermined voltage by controlling a discharge pathway at an output terminal according to an analog control signal, the analog control signal is proportional to voltage overshoot of the predetermined voltage.

2. The apparatus of claim 1, wherein the discharge pathway is directly connected to the output terminal and controlling the discharge pathway includes controlling a discharge current between the output terminal and a ground terminal.

3. The apparatus of claim 2, wherein the discharge pathway is formed by a PMOS device that has a first terminal directly connected to the output terminal, a second terminal directly connected to the ground terminal and a gate that receives the analog control signal.

4. The apparatus of claim 3, further comprising an NMOS device that has a first terminal connected to a supply voltage and a second terminal connected to the first terminal of the PMOS device and to the output terminal to form a push-pull output stage.

5. The apparatus of claim 1, wherein the analog control signal is generated by a bias circuit that includes a first NMOS device, a second NMOS device and a current source connected in series between a supply voltage and ground with an output for the analog control signal located between the second NMOS device and the current source.

6. The apparatus of claim 5, wherein a gate terminal of the first NMOS device receives a gate signal that is proportional to the overshoot of the predetermined voltage.

7. The apparatus of claim 6, wherein the gate signal is generated by a first NMOS device controlled by an output of an amplifier, the amplifier includes a first input terminal connected to receive an indicator signal that indicates voltage at the output terminal, a second input terminal connected to the predetermined voltage, and an output terminal connected to the gate terminal of the first NMOS device.

8. The apparatus of claim 7, wherein the first NMOS device, a resistor and a second NMOS device are connected in series between ground and a supply voltage.

9. The apparatus of claim 1, wherein the plurality of nonvolatile memory cells are arranged in a 3D NAND structure.

10. The apparatus of claim 1, wherein the one or more control circuits are formed on a control die, the plurality of nonvolatile memory cells are formed on a memory die and the control die and memory die are bonded to form an integrated memory assembly.

11. A method comprising:
generating a memory access voltage at an output terminal that is connected to one or more word lines of a NAND memory structure;
providing an analog feedback signal from the output terminal;
generating a gate voltage according to a difference between the analog feedback signal and a reference voltage;
from the gate voltage, generating an analog control signal that is a function of the difference between the analog feedback signal and the reference voltage; and
discharging the output terminal through a discharge pathway, a discharge current through the discharge pathway controlled by the analog control signal such that discharge current increases according to the difference between the analog feedback signal and the reference voltage.

12. The method of claim 11, wherein the discharge pathway is formed by a PMOS device and discharging the output terminal includes applying the analog control signal to a gate terminal of the PMOS device to cause a discharge current that increases in proportion to the difference between the analog feedback signal and the reference voltage.

13. The method of claim 12, wherein providing the analog feedback signal from the output terminal includes providing the analog feedback signal from a node of a voltage divider that is connected between the output terminal and ground.

14. The method of claim 11, wherein generating the gate voltage includes providing the analog feedback signal and the reference voltage to input terminals of an amplifier such that an output of the amplifier increases according to the difference between the analog feedback signal and the reference voltage.

15. The method of claim 14, wherein generating the gate voltage further includes providing the output of the amplifier to a control gate of a first NMOS device that is connected in series with a resistor and a second NMOS device between ground and a supply voltage, the gate voltage generated between the first NMOS device and the resistor.

16. The method of claim 11, wherein generating the memory access voltage at the output terminal includes providing the gate voltage to an NMOS device that is connected between a supply voltage and the output terminal, the discharge pathway is formed by a PMOS device and the NMOS device and PMOS device form a push-pull output stage.

17. The method of claim 11, wherein the one or more word lines are unselected word lines in a read or write operation, the memory access voltage is a pass voltage and discharging the output terminal mitigates pass voltage overshoot on the unselected word lines.

18. A storage system comprising:
a plurality of nonvolatile memory cells connected by word lines; and
means for applying a pass voltage on one or more unselected word lines in a read or write operation directed to the plurality of nonvolatile memory cells and limiting overshoot of the pass voltage by controlling a discharge current from an output terminal according to an analog control signal where the discharge current is proportional to the overshoot of the pass voltage.

19. The storage system of claim 18, wherein the plurality of nonvolatile memory cells are arranged in a 3D NAND structure.

20. The storage system of claim 19, wherein the 3D NAND structure is located on a memory die, the means for applying a pass voltage is located on a control die and the control die is bonded to the memory die to form an integrated memory assembly.
